(19) United States
(12) Patent Application Publication
(10) Pub. No.: US 2011/0308613 A1
(43) Pub. Date: Dec. 22, 2011

(54) Photovoltaic Devices with Nanostructure/Conjugated Polymer Hybrid Layer and its Matched Electron Transporting Layer

(75) Inventors: Tsung-Wei Tseng, Taipei (TW); Wei-Fang Su, Taipei (TW); Chun-Wei Chen, Taipei (TW); Yun-Yue Lin, Taipei (TW)

(73) Assignee: National Taiwan University, Taipei (TW)

(21) Appl. No.: 13/206,912

(22) Filed: Aug. 10, 2011

Related U.S. Application Data
(62) Division of application No. 11/693,706, filed on Mar. 29, 2007.

(30) Foreign Application Priority Data
Jun. 30, 2006 (TW) 095123926

(51) Int. Cl. H01L 31/0256; H01L 31/0272; H01L 31/032; H01L 31/0296; H01L 31/0304; H01L 31/0312; H01L 31/0264; H01L 31/028

(52) U.S. Cl. 136/260; 136/263; 136/262; 136/261

(57) ABSTRACT

The present invention discloses a photovoltaic device comprising a multilayer structure for generating and transporting charge, wherein the multilayer structure comprises: a substrate; an anode layer; a hole transporting layer; a first nanostructure/conjugated polymer hybrid layer; an network-shaped electron transporting layer matched to the hybrid layer; and a cathode layer. The mentioned electron transporting layer is composed of a plurality of second nanostructures, and the plurality of second nanostructures is staked on each other, so as to form the interconnecting network. Furthermore, this invention also discloses methods for forming the photovoltaic device.

### CROSS REFERENCE TO RELATED APPLICATIONS

This is a divisional of U.S. Ser. No. 11/693,706, filed Mar. 29, 2007 by the same inventors, and claims priority there from. This divisional application contains rewritten claims to the restricted-out subject matter of original claims.

### GOVERNMENT INTERESTS

The invention described and claimed herein was made in part utilizing funds supplied by the United States Air Force under contract NO. FA5209-04-P-0500 AOARD 04-23 between the United States Air Force and the National Taiwan University. The government has certain rights to the invention.

### BACKGROUND OF THE INVENTION

1. Field of the Invention

The present invention is generally related to photovoltaic devices, and more particularly to photovoltaic devices with nanostructure/conjugated polymer hybrid layer (hereinafter as photoactive layer) and its matched electron transporting layer.

2. Description of the Prior Art

Conjugated polymers have great utility for fabrication of large area, physically flexible and low cost solar cells. A basic requirement for making efficient photovoltaic devices is that the free charge carriers produced upon photoexcitation of the photoactive material must be transported through the device to the electrode without recombining with oppositely charged carriers. Photovoltaic devices merely composed of conjugated polymers as the only active material have extremely low electron mobility and, thus, limited performance.

Recent developments have shown that the use of interpenetrating electron donor-acceptor heterojunctions such as polymer:fullerene, polymer:polymer and polymer:nanocrystal can yield highly efficient photovoltaic conversions. Electron acceptors have been intermixed at the nanometre scale with an organic semiconducting polymer to obtain high charge separation yield. Following electron transfer, both electron and hole must be transported to the electrode before back recombination can occur. However, in some cases, electron transport is limited by inefficient hopping along poorly formed conduction paths. Thus, new charge transport routes are desirable to achieve efficient electron conduction.

### SUMMARY OF THE INVENTION

In accordance with the present invention, new photovoltaic devices with nanostructure/conjugated polymer hybrid layer and its matched electron transporting layer are provided in corresponding to both economic effect and utilization in industry.

One objective of the present invention is to insert a thin layer of nanostructure between the photoactive layer and the cathode for an efficient electron transport, so as to enhance the photovoltaic device performance.

Another objective of the present invention is to provide photoactive layer and its “matched” electron transporting layer. The barrier for electron injection directly from the photoactive layer to the metal cathode is large; this will reduce efficiency. Therefore, an electron transporting layer is inserted between the cathode and the photoactive layer to provide an intermediate step to aid electron injection, and this electron transporting layer is called “matched electron transporting layer” in this invention. The photoactive layer is composed of nanostructure/conjugated polymer hybrid material, and more preferred, the same nanostructures are used to form the electron transporting layer. Hence, this combination is excellent for offering a better connectivity of electron transport path to cathode.

Accordingly, the present invention discloses a photovoltaic device comprising a multilayer structure for generating and transporting charge, wherein the multilayer structure comprises: a substrate; an anode layer; a hole transporting layer; a first nanostructure/conjugated polymer hybrid layer; an network-shaped electron transporting layer matched to the hybrid layer; and a cathode layer. The mentioned electron transporting layer is composed of a plurality of second nanostructures, and the plurality of second nanostructures is staked on each other, so as to form the interconnecting network. Furthermore, this invention also discloses methods for forming the photovoltaic device.

### BRIEF DESCRIPTION OF THE DRAWINGS

FIG. 1 shows anatase TiO₂ nanorod structure images observed by TEM and HRTEM (inset);

FIG. 2 is an absorption spectra of MEH-PPV films (solid line) and MEH-PPV:TiO₂ nanorod (52 wt %) hybrid (dashed line) of thickness 80 nm, and photoluminescence spectra of MEH-PPV films (dotted line) and MEH-PPV:TiO₂ nanorod (52 wt %) hybrid (dash-dotted line), excited at 450 nm; and

FIG. 3 shows (a) Schematic structure of standard configuration MEH-PPV:TiO₂ nanorod hybrid photovoltaic devices. (b) Schematic structure of MEH-PPV:TiO₂ nanorod hybrid photovoltaic device included a TiO₂ nanorod layer;

FIG. 4 are AFM images showing the surface morphology of an MEH-PPV:TiO₂ nanorod hybrid film and TiO₂ nanorod film. (a) Height image of spin-cast film of MEH-PPV:TiO₂ (52 wt %) nanorod hybrid. The image size is 1.5 μm×1.5 μm, and the vertical scale is 30 nm. (b) Phase image of MEH-PPV:TiO₂ (52 wt %) nanorod hybrid film. The image size is 1.5 μm×1.5 μm, and the vertical scale is 30°. (c) Height image of spin-cast film of TiO₂ nanorods on MEH-PPV:TiO₂ nanorod hybrid film. The image size is 1.5 μm×1.5 μm, and the vertical scale is 30 nm. (d) Phase image of TiO₂ nanorod film on MEH-PPV:TiO₂ nanorod hybrid film. The image size is 1.5 μm×1.5 μm, and the vertical scale is 30°;

FIG. 5 shows (a) Flat band energy-level diagram of ITO/PEDOT:PSS/MEH-PPV:TiO₂ nanorods/TiO₂ nanorods/Al devices. (b) Plots of current density as the function of applied voltage for three different configuration devices under 0.09 mW cm⁻² illumination at 560 nm. (MEH-PPV:TiO₂ nanorods (52 wt %) (dashed line); MEH-PPV:TiO₂ nanorods (52 wt %)/TiO₂ nanorods (solid line) and MEH-PPV:TiO₂ nanorods (52 wt %)/MEH-PPV (dotted line)). (c) Plot of current density versus voltage in the dark (dashed line); and under 0.05 mW cm⁻² illumination at 565 nm (solid line, Voc=0.86 V, Jsc=−0.0035 mA cm⁻², FF=0.35 and η=2.2%). The inset shows the external quantum efficiency versus wavelength of the device. The device structure is ITO/PEDOT:PSS/MEH-PPV:TiO₂ nanorods (52 wt %)/TiO₂ nanorods/Al. (d) The corresponding I-V curve of the ITO/PEDOT:PSS/MEH-PPV:TiO₂ nanorods (52 wt %)/TiO₂ nanorods/Al device at AM 1.5 illumination (100 mW cm−2). (Voc=1.15 V, Jsc=−1.7 mA cm⁻², FF=0.25 and η=0.49%). The logarithmic I-V characteristic of the device is shown in the inset.

### DESCRIPTION OF THE PREFERRED EMBODIMENTS

What probed into the invention are photovoltaic devices with nanostructure/conjugated polymer hybrid layer and its matched electron transporting layer. Detailed descriptions of the production, structure and elements will be provided in the following in order to make the invention thoroughly understood. Obviously, the application of the invention is not confined to specific details familiar to those who are skilled in the art. On the other hand, the common elements and procedures that are known to everyone are not described in details to avoid unnecessary limits of the invention. Some preferred embodiments of the present invention will now be described in greater detail in the following. However, it should be recognized that the present invention can be practiced in a wide range of other embodiments besides those explicitly described, that is, this invention can also be applied extensively to other embodiments, and the scope of the present invention is expressly not limited except as specified in the accompanying claims.

In a first embodiment of the present invention, a photovoltaic device comprising a multilayer structure for generating and transporting charge is disclosed, wherein the multilayer structure comprises: a substrate; an anode layer; a hole transporting layer; a first nanostructure/conjugated polymer hybrid layer; an network-shaped electron transporting layer matched to the hybrid layer; and a cathode layer. The mentioned electron transporting layer is composed of a plurality of second nanostructures, and the plurality of second nanostructures is staked on each other, so as to form the interconnecting network. Furthermore, the material of the first nanostructure can be the same with that of the second nanostructure; or the material of the first nanostructure can be different from that of the second nanostructure.

Nanostructures are considered to be more attractive in photovoltaic applications due to their large surface-to-bulk ratio, giving an extension of interfacial area for electron transfer, and higher stability. The charge separation process must be fast compared to radiative or nonradiative decays of the singlet exciton, leading to quenching of the photoluminescence (PL) intensities. However, electron transport in the polymer/nanostructure hybrid is usually limited by poorly formed conduction path. Thus, one-dimensional nanostructures are preferable over nanoparticles for offering direct pathways for electric conduction. In this invention, the configuration of the nanostructure comprises one of the following group: nanocrystal, nanoparticle, nanotube, nanowire, quantum wells, and more preferred, nanostructure with aspect ratio ranging from 2 to 200.

In this embodiment, the cross section of the first and second nanostructure ranges from 10 nm to 200 nm. The first nanostructure content of the hybrid layer ranges from 1 wt % to 99 wt %, and 40 wt % to 60 wt % is preferred. Additionally, the material of the first and second nanostructure is independently selected from the following group: inorganic material, metal material, and a mixture of metal and inorganic material. In the first case, the metal nanostructure comprises one of the group consisting of: gold, silver, platinum and alloys thereof. In the second case, the material of the inorganic nanostructure can be carbon, metal oxides or semiconductors (eg. Group II-VI, Group III-V, Group IV semiconductors or alloys thereof). Some common inorganic nanostructure comprises one of the group consisting of: TiO₂, CdS, CdSe, GaAs, GaP, ZnO, Fe₂O₃, SnO₂, SiC, InN, InGaN, GaN, PbS, Bi₂S₃, Cu—In—Ga—Se, Cu—In—Ga—S and alloys thereof. Furthermore, in the third case, the inorganic nanostructure can comprise more than 2 materials, for example: 1) the inorganic nanoparticles comprises TiO₂ and at least one II-VI semiconductor; 2) the inorganic nanoparticles comprises TiO₂ doped with at least one transition metal ion or Lanthanide ion; 3) inorganic nanoparticles comprises at least two oxide, wherein one oxide has low bandgap (≦3.0 eV) and the other oxide exhibits high conductivity (≦100 Ω/sq).

Moreover, the conjugated polymer comprises one of the group consisting of: poly-paraphenylene (PPP), poly-p-phenylenevinylene (PPV), poly-thiophene (PT), poly-fluorene (PF), poly-pyrrole (PPy), (poly(2-methoxy5-(2′-ethylhexyloxy)p-phenylenevinylene) (MEH-PPV), poly[2 -methoxy-5-(3′,7′-dimethyloctyloxy)-1,4-phenylene vinylene] (MDMO-PPV), poly(3-hexylthiophene) (P3HT) and their copolymer or derivatives.

A basic requirement for a photovoltaic material is photoconductivity; that is, generating a charge upon illumination. Subsequently, these charges must drift (under an applied electric field) toward electrodes for collection. The mechanisms which determine the performance of a photovoltaic device will involve the photo-electron generation rate, charge separation (electron-hole dissociation), and charge transport. In this invention, charge separation in the composite material is tremendously enhanced by increasing the interface area between electron-donating materials and electron-accepting materials. Furthermore, the charge separation process must be fast compared to the radiative and non-radiative decays of the excitons, which typically occur with a time constant in the range of 100-1000 ps. The problem of transport of carriers to the electrodes without recombination is another important issue to solve, since it requires that once the electrons and holes are separated onto two different materials, each carrier has a pathway to the appropriate electrode.

In a second embodiment of the present invention, a method for fabricating a photovoltaic device is disclosed. First, a multilayer structure with a substrate, an anode layer, and a hole transporting layer is provided. Next, a first solvent, a plurality of first nanostructure and a conjugated polymer are mixed to form a mixture. Then, a first depositing process is performed to deposit the mixture onto the hole transporting layer, so as to form a first nanostructure/conjugated polymer hybrid layer, wherein the first depositing process comprises a first drying process to remove the first solvent in the mixture. Afterwards, a plurality of second nanostructure is dispersed in a second solvent, so as to form a solution. Next, a second depositing process is performed to deposit the solution onto the first nanostructure/conjugated polymer hybrid layer, to form a network-shaped electron transporting layer, wherein the second depositing process comprises a second drying process to remove the second solvent in the solution. Finally, a cathode layer is formed on the electron transporting layer.

In this embodiment, the first depositing process and the second depositing are independent selected from the group consisting of: spraying, roller coating, blade coating, dip-coating, and spin-coating. Furthermore, the material of the first nanostructure can be the same with that of the second nanostructure; or the material of the first nanostructure can be different from that of the second nanostructure. The cross section of the first and second nanostructure ranges from 10 nm to 200 nm. The first nanostructure content of the hybrid layer ranges from 1 wt % to 99 wt %, and 40 wt % to 60 wt % is preferred. Additionally, the material of the first and second nanostructure and the material of the conjugated polymer comprises is described in the first embodiment.

### EXAMPLE 1

### Experimental Details

The controlled growth of high aspect ratio anatase titanium dioxide nanorods was accomplished by hydrolyzing titanium tetraisopropoxide according to the literature with some modifications [Cozzoli P D, Kornowski A and Weller H 2003 J. Am. Chem. Soc. 125 14539]. Typically, oleic acid (120 g, Aldrich, 90%) was stirred vigorously at 120° C. for 1 h in a three neck flask under Ar flow, then allowed to cool to 90° C. and maintained at this temperature. Titanium isopropoxide (17 mmol, Aldrich, 99.999%) was then added into the flask. After stirring for 5 min, trimethylamine-N-oxide dihydrate (34 mmol, ACROS, 98%) in 17 ml water was rapidly injected. Trimethylamine-N-oxide dihydrate was used as a catalyst for polycondensation. This reaction was continued for 9 h to have complete hydrolysis and crystallization. Subsequently, the TiO₂ nanorod product was obtained (4 nm in diameter, 20-40 nm in length). The nanorods were washed and precipitated by ethanol repeatedly to remove any residual surfactant. Finally, the TiO₂ nanorods were collected by centrifugation and then redispersed in chloroform or toluene.

The indium-tin-oxide (ITO)/poly (3,4-ethylenedioxythiophene)-poly(styrenesulfonate) (PEDOT:PSS)/MEH-PPV:TiO₂ nanorods/Al device was fabricated in the following manner. An ITO glass substrate with a sheet resistance of 15 Ω/square (Merck) was ultrasonically cleaned in a series of organic solvents (ethanol, methanol and acetone). A 60 nm thick layer of PEDOT:PSS (Aldrich) was spin-cast onto the ITO substrate; this was followed by baking at 100° C. for 10 min. TiO₂ nanorods in toluene and MEH-PPV (Aldrich, molecular weight 40,000-70,000 g mol⁻¹) in chloroform/1,2-dichlorobenzene (1:1 to 100:1, vol/vol) were thoroughly mixed and spin-cast on the top of the PEDOT:PSS layer. The thickness of MEHPPV:TiO₂ nanorod film was 180 nm. Then, the 100 nm Al electrode was vacuum deposited on the hybrid layer.

By inserting the TiO₂ nanorod thin film between the MEHPPV:TiO₂ nanorod hybrid and Al electrode, an improved device with a configuration of ITO/PEDOT:PSS/MEHPPV:TiO₂ nanorods/TiO₂ nanorods/Al was made. The TiO₂ nanorods dissolved in chloroform:ethanol=4:1 solution were spin-cast on the top of the MEH-PPV:TiO₂ nanorods hybrid to obtain a TiO₂ nanorod thin film of 70 nm thickness. In order to minimize the redissolving of MEH-PPV:TiO₂ layer, we have spin-coated concentrated nanorods solution (0.05 ml, 25 mg ml⁻¹) on the MEH-PPV:TiO₂ nanorod hybrid at very high speed (6000 rpm). An ITO/PEDOT:PSS/MEH-PPV:TiO₂ nanorods/MEH-PPV/Al photovoltaic device was fabricated as a reference. A 130 nm MEH-PPV layer on an MEH-PPV:TiO₂ nanorod hybrid was made by spin coating. The MEH-PPV in chloroform (20 mg ml⁻¹) solution was also spin-cast at a very high speed of 6000 rpm.

The crystalline structure of the nanorods was studied using x-ray diffraction (XRD) (Philips PW3040 with filtered Cu Kα radiation (λ=1.540 56° A)). The analysis of TiO₂ nanorods was performed using a JOEL JEM-1230 transmission electron microscope (TEM) operating at 120 keV or a 2000FX high resolution transmission electron microscope (HRTEM) at 200 keV. The film thickness was determined by an α-stepper (DEKTAK 6M 24383). The film morphology was observed by atomic force microscopy (AFM) (Digital Instruments Nanoscope III). The current-voltage (I-V) characterization (Keithley 2400 source meter) was performed under 10⁻³ Torr vacuum, with monochromatic illumination at a defined beam size (Oriel Inc.). The Air Mass (AM) 1.5 condition was measured using a calibrated solar simulator (Oriel Inc.) with irradiation intensity of 100 mW cm⁻². Once the power from the simulator was determined, a 400 nm cutoff filter was used to remove the UV light. The 80 nm MEH-PPV and MEHPPV:TiO₂ films were cast on quartz substrate to obtain UV-Visible absorption (Jasco V-570) and photoluminescence (PL) (Perkin-Elmer FS-55) measurements.

### EXAMPLE 2

### Results and Discussion

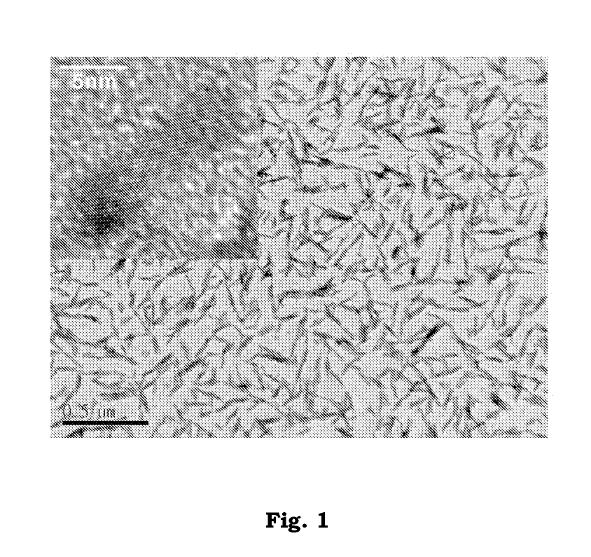

The TEM image of TiO₂ nanorods (as shown in FIG. 1) reveals that the TiO₂ nanorod dimension is 20-40 nm in length and 4-5 nm in diameter. The HRTEM image indicates that the TiO₂ nanorods had high crystallinity.

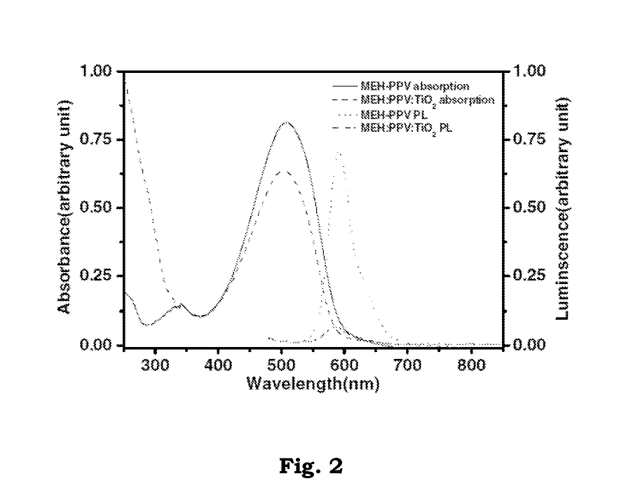

FIG. 2 shows the absorption and PL spectra of pristine MEH-PPV and MEH-PPV:TiO₂ nanorod hybrid films respectively. The optical density of the absorption spectrum in the hybrid increases with respect to the pristine polymer, and whose form is the result of contributions from each component. The absorption at wavelength less than 350 nm results mainly from the TiO₂ nanorods. In contrast, the yield of the PL emission decreases substantially, suggesting the occurrence of significant PL quenching in the hybrid. Decreases in PL yield are attributed to the quenching of the MEH-PPV PL emission by the TiO₂ nanorods, acting as an electron accepting species, where significant charge separation takes place due to large interfacial areas for exciton dissociation.

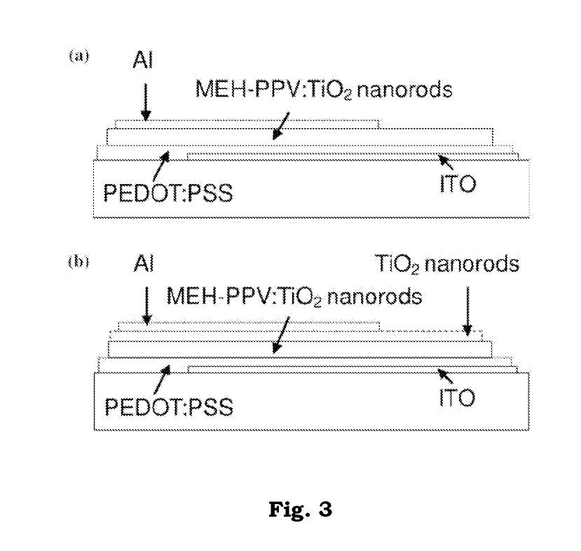

As a starting point, we made a standard hybrid device structure similar to those previous reported polymer: nanocrystal photovoltaic devices, resulting in devices with external quantum efficiencies of the order up to 10%. A schematic diagram of our standard device configuration is shown in FIG. 3(a), which consists of a transparent indium-tin-oxide (ITO) conducting electrode, poly(3,4-ethylenedioxythiophene)-poly(styrenesulfonate) (PEDOT:PSS), the MEH-PPV:TiO₂ nanorod hybrid film, and an aluminium (Al) electrode. We have further modified the device configuration by including an additional electron conducting layer of TiO₂ nanorods sandwiched between the active layer and the aluminium electrode to improve device performance, as shown in FIG. 3(b).

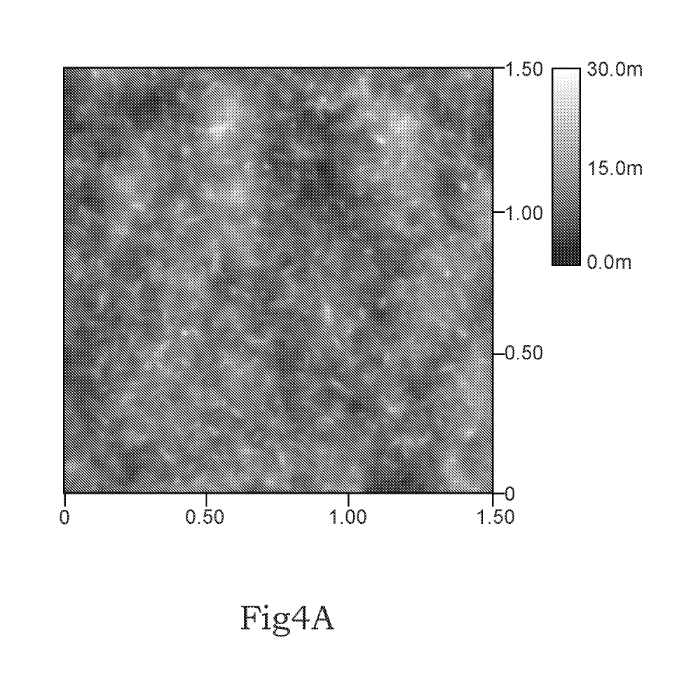

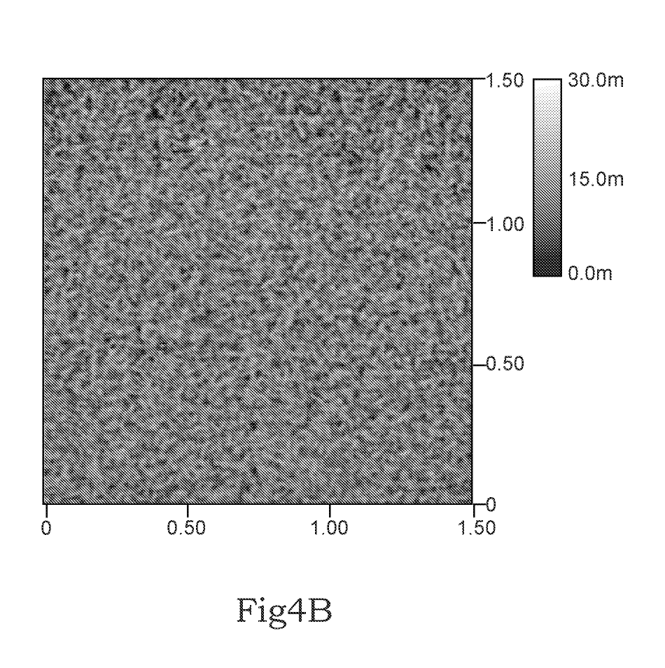

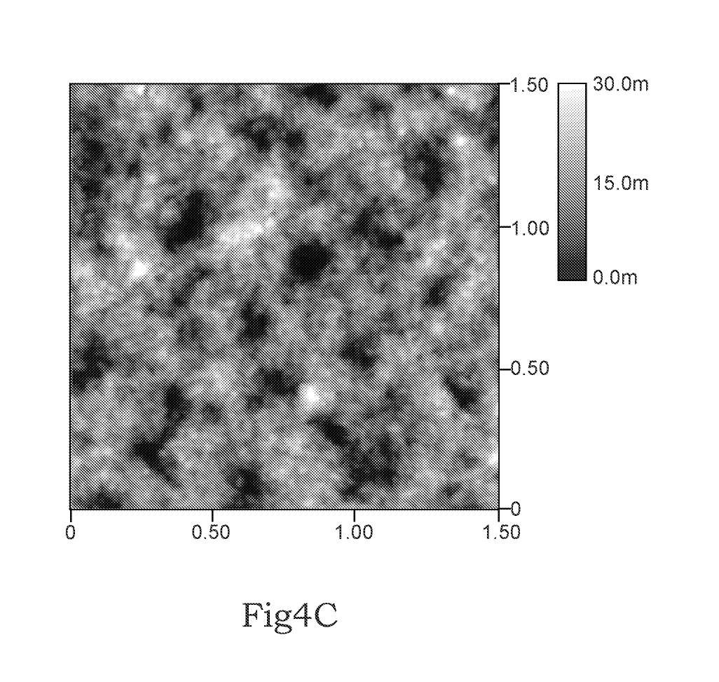

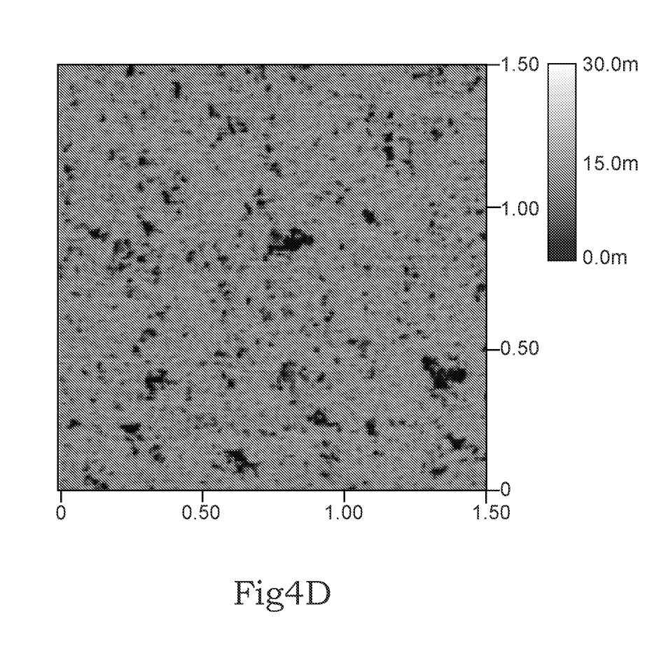

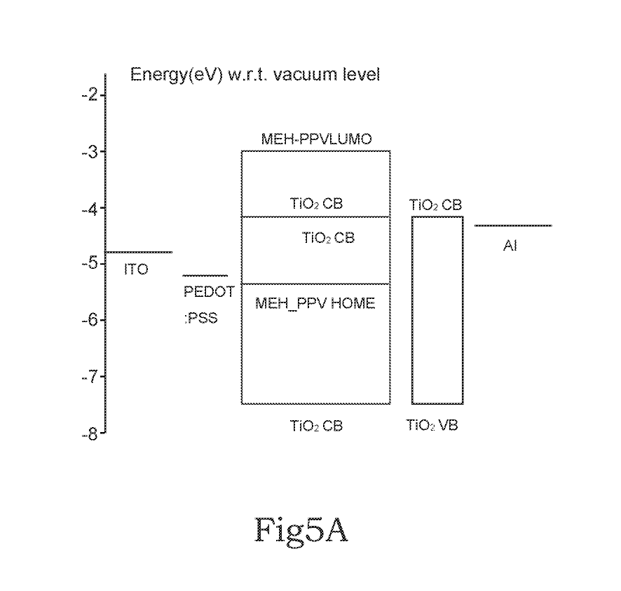

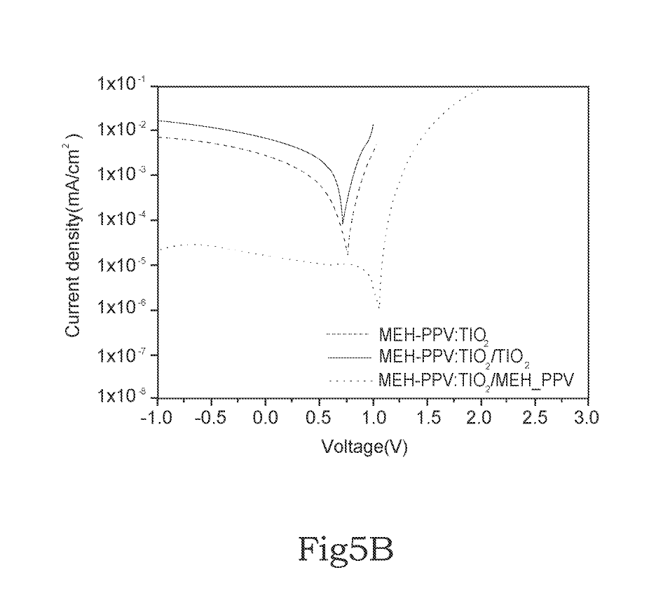

We used tapping-mode AFM to investigate the structures and film morphology of these devices. FIG. 4(a) shows the smooth topography of an MEH-PPV:TiO₂ nanorod hybrid with roughness 2 nm. The TiO₂ nanorods were randomly distributed in the polymer matrix for the interconnecting work formation. FIG. 4(b) shows the phase image of an MEH-PPV: TiO₂ nanorod hybrid. Tapping-mode AFM can also give information about the materials at the film surface via phase images. Because a hard material generally shows a positive phase shift with respect to a soft material due to the cantilever oscillation being related to the power dissipated in a nonelastic tip-sample interaction, the bright areas in FIG. 4(b) are interpreted as the harder material of TiO₂ nanorods and the darker areas as the soft material of polymer. A homogenous distribution of TiO₂ nanorods in polymer is observed in FIG. 4(b). FIG. 4(c) shows the surface topography of a spin-cast TiO₂ nanorod layer on an MEH-PPV:TiO₂ nanorod hybrid. A feature of aggregation of nanorod structure was found. The TiO₂ nanorod thin film exhibits a porous structure of relatively high film roughness. FIG. 4(d), the phase image of a TiO₂ nanorod thin film, shows a single phase of bright areas consisting of TiO₂ nanorods. The dark region in FIG. 4(d) could be seen as deep pores of the TiO₂ nanorod thin film, which is consistent with the surface topography observed in FIG. 4(b). From the results above, we have constructed an interconnecting network in an MEH-PPV:TiO₂ nanorod photoactive hybrid and a thin film composed of mere TiO₂ nanorods sandwiched between a hybrid layer and Al electrode through our process conditions.

An optimal composition between polymer and nanorods is required to achieve balanced exciton dissociation and charge transport. We investigated the effect of TiO₂ nanorod compositions on device performance. The best performance of this type of device was obtained at a concentration of MEHPPV:TiO₂ (52 wt %). Lower power conversion efficiencies were obtained either at lower TiO₂ concentration (MEHPPV:TiO₂ (40 wt %)) or higher concentration (MEH-PPV:TiO₂ (64 wt %)). This implies that, under those conditions, MEH-PPV:TiO₂ (40 wt %) or MEH-PPV:TiO₂ (64 wt %), polymer-TiO₂ interfacial areas were not maximized for exciton dissociation or that the donor-acceptor interpenetrating networks formed cannot meet the requirements for the most efficient charge transport. We have varied the compositions of TiO₂ in the hybrid, the film thicknesses of the active layer and the types of solvent to achieve the optimal performance of the standard configuration device; however, the external quantum efficiency was limited to less than 10%.

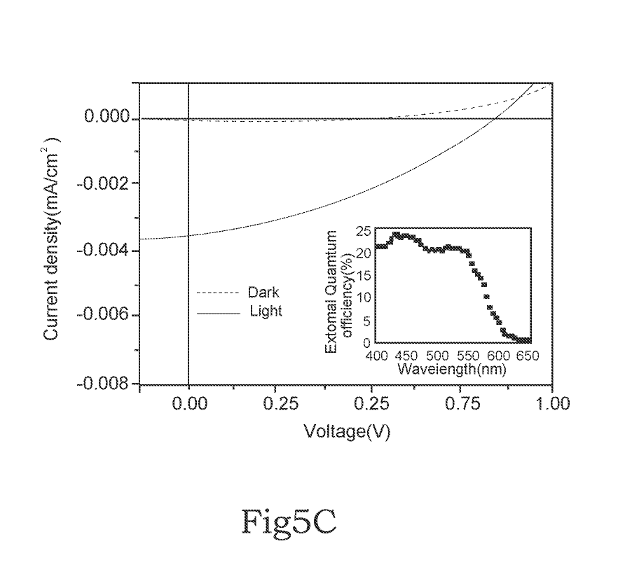

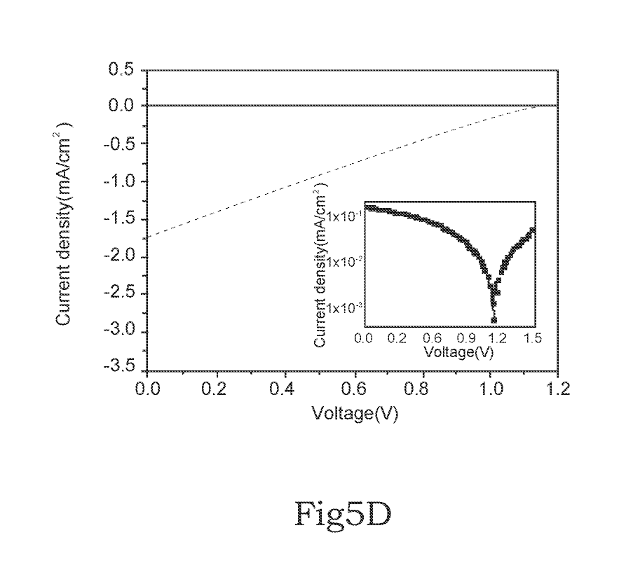

Based upon considering the energy levels of the respective materials in the device, a TiO₂ nanorod layer inserted between the active layer and the aluminium electrode is appropriate for offering a better connectivity of electron transport path to the electrode. The functions of the TiO₂ nanorod layer can be explained by the band diagram in FIG. 5(a). The energy level diagram demonstrates that the TiO₂ nanorod layer acts as a hole-blocking electron-transporting layer in this device. As the electron-hole pairs are generated by incident light, an efficient charge separation occurs at the interface of the MEH-PPV:TiO₂ nanorod hybrid. Electrons move toward the aluminium electrode and holes move toward the ITO electrode. The addition of the continuous TiO₂ nanorod thin film allows for the current to be conducted effectively and also prevents electrons from back recombination with holes in the MEHPPV. The TiO₂ nanorod layer acts as a hole-blocking layer because of lower valence band value. In contrast, on inserting a thin MEH-PPV layer instead, the device is energetically unfavorable for electron transport.

FIG. 5(b) shows the current-voltage response of the devices with and without a TiO₂ nanorod layer. The device containing a TiO₂ nanorod layer increases the short-circuit current density by a factor of 2.5 with respect to a device without the layer. For a comparison, the thin TiO₂ nanorod layer was replaced with a thin MEH-PPV layer and a ˜3 order of magnitude of decrease in the short-circuit current was found. Apart from the hole-blocking electron-transporting function of TiO₂ nanorod layer mentioned above, the interfaces introduced (MEH-PPV:TiO₂/TiO₂ and TiO₂/Al) seem more beneficial to charge transport as compared to the MEH-PPV:TiO₂/Al contact. The TiO₂ nanorod layer can be connected to the TiO₂ nanorods in the active hybrid. In addition, the rough surface of the TiO₂ layer can lead to stronger contact and increased contact area to the Al electrode. Besides, inserting this layer can create a second interfacial area for exciton dissociation that might increase the charge transfer rate. To introduce an additional titanium oxide thin film as a hole-blocking electron-transporting layer through various approaches has been presented in producing higher efficiency heterojunction organic solar cells. Here we present a thin film of crystalline TiO₂ nanorods made via a fully solution process that can lead to improvement in device performance. The TiO₂ nanorod thin film could be explored as a promising hole blocking electron-transporting layer in photovoltaic devices.

An equivalent circuit has frequently been used to describe the electric behavior of a photovoltaic device. We further analyzed the characteristics of the devices based upon this equivalent circuit. The current density versus voltage characteristics can be described by the following equations:

$$\begin{matrix}I = {I}_{0} \times [ exp ( e \frac{U - IRs}{nkT} ) - 1 ] + \frac{U - IRs}{{R}_{SH}} - {I}_{PH} & ( 1 ) \\ {R}_{S} = {lim}_{V -> ∞} ( \frac{d V}{d I} ) & ( 2 ) \\ {R}_{SH} \approx \frac{d V}{d I} ( V = 0 ) {R}_{S} ≪ {R}_{SH} . & ( 3 )\end{matrix}$$

where I₀ is the saturation current, e is the magnitude of the electronic charge, U is the applied voltage, n is the ideality factor, k is Boltzmann's constant, T is the absolute temperature, R_{S} is the series resistance, R_{SH} is the shunt resistance and I_{PH} is the photocurrent. The current-voltage characteristics are largely dependent on the series and shunt resistance. A lower series resistance means that higher current will flow through the device. High shunt resistance corresponds to fewer shorts or leaks in the device. The ideal cell would have a series resistance approaching zero and shunt resistance approaching infinity. The series resistance can be estimated from the inverse slope at a positive voltage where the I-V curves become linear. The shunt resistance can be derived by taking the inverse slope of the I-V curves around 0 V.

The R_{S} and R_{SH} were analyzed from the I-V curves of the devices (FIG. 5(b)); it is found that a significant, nearly 60%, reduction in R_{S} occurred as the TiO₂ nanorod layer was introduced into the device. A slight reduction of the shunt resistance was observed also. The series resistance can be expressed as the sum of the bulk and interfacial resistance. It is likely that two interfaces that have been introduced (MEHPPV:TiO₂/TiO₂ and TiO₂/Al) combined with the TiO₂ nanorod layer offer a much lower magnitude of series resistance as compared to the MEH-PPV:TiO₂/Al contact. The introducing of the TiO₂ layer decreases the series resistance in the device and thereby increases the current.

The performance of the device with a structure of ITO/PEDOT:PSS/MEH-PPV:TiO₂ nanorods (52 wt %)/TiO₂ nanorods/Al was evaluated. The I-V characteristic of the device exhibits a short-circuit current density (Jsc) of −0.0035 mA cm⁻², an open circuit voltage (V_{OC}) of 0.86 V and a fill factor (FF) of 0.35. A power conversion efficiency (η) of 2.2% is achieved under 0.05 mW cm⁻² illumination at 565 nm (FIG. 5(c)). The inset shows the external quantum efficiency (EQE) of the device under illumination. A maximum EQE of 24% under 0.07 mW cm⁻² at 430 nm is achieved. FIG. 5(d) presents the characteristics of the device tested under AM 1.5 illumination with an intensity of 100 mW cm⁻². The Jsc, FF, and V_{OC} are −1.7 mA cm⁻², 0.25, and 1.15 V, respectively for the device, yielding a power conversion efficiency of 0.49%. Work to optimize the device efficiency is still under way, to achieve better device efficiency.

In the above preferred embodiments, the present invention uses nanostructure as efficient electron acceptors and transport components in the active layer of the hybrid organic photovoltaic device. Moreover, electron transporting layer, formed by staking nanostructures, between the active layer and the cathode provides an enlarged interconnecting network for electrical transport near the cathode, leading to a dramatically increase in the short-circuit current under illumination. Further improvements in the device performance could be accomplished by controlling the nanostructure sizes and by improving the polymer:nanostructure interface.

Obviously many modifications and variations are possible in light of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. A photovoltaic device comprising a multilayer structure for generating and transporting charge, wherein the multilayer structure comprises:
a substrate;
an anode layer;
a hole transporting layer;
a first nanostructure/conjugated polymer hybrid layer;
an network-shaped electron transporting layer matched to the hybrid layer, wherein the electron transporting layer is composed of a plurality of second nanostructures, and the plurality of second nanostructures is staked on each other, so as to form the interconnecting network; and
a cathode layer.

2. The photovoltaic device as claimed in claim 1, wherein the material of the first nanostructure is the same with that of the second nanostructure.

3. The photovoltaic device as claimed in claim 1, wherein the material of the first nanostructure is different from that of the second nanostructure.

4. The photovoltaic device as claimed in claim 1, wherein the cross section of the first and second nanostructure ranges from 10 nm to 200 nm.

5. The photovoltaic device as claimed in claim 1, wherein the material of the first and second nanostructure is independently selected from the following group: inorganic material, metal material, and a mixture of metal and inorganic material.

6. The photovoltaic device as claimed in claim 5, wherein the material of the inorganic nanostructure comprises one of the group consisting of: Group II-VI, Group III-V, Group IV semiconductors and alloys thereof.

7. The photovoltaic device as claimed in claim 5, wherein the material of the inorganic nanostructure comprises one of the group consisting of: TiO₂, CdS, CdSe, GaAs, GaP, ZnO, Fe₂O₃, SnO₂, SiC, InN, InGaN, GaN, PbS, Bi₂S₃, Cu—In—Ga—Se, Cu—In—Ga—S and alloys thereof.

8. The photovoltaic device as claimed in claim 5, wherein the inorganic nanostructure comprises TiO₂ and at least one II-VI semiconductor.

9. The photovoltaic device as claimed in claim 5, wherein the inorganic nanostructure comprises TiO₂ doped with at least one transition metal ion or Lanthanide ion.

10. The photovoltaic device as claimed in claim 5, wherein the inorganic nanostructure comprises at least two oxide, wherein the bandgap of one oxide is equivalent to or less than 3.0 eV, and the sheet resistance of the other oxide is equivalent to or less than 100 Ω/sq.

11. The photovoltaic device as claimed in claim 5, wherein the metal nanostructure comprises one of the group consisting of: gold, silver, platinum and alloys thereof.

12. The photovoltaic device as claimed in claim 1, wherein the first nanostructure content of the hybrid layer ranges from 1 wt % to 99 wt %.

13. The photovoltaic device as claimed in claim 1, wherein the first nanostructure content of the hybrid layer ranges from 40 wt % to 60 wt %.

14. The photovoltaic device as claimed in claim 1, wherein the conjugated polymer comprises one of the group consisting of: poly-paraphenylene (PPP), poly-p-phenylenevinylene (PPV), poly-thiophene (PT), poly-fluorene (PF), poly-pyrrole (PPy), (poly(2 -methoxy5-(2′-ethylhexyloxy)p-phenylenevinylene) (MEH-PPV), poly[2-methoxy-5-(3′,7′-dimethyloctyloxy)-1,4-phenylene vinylene] (MDMO-PPV), poly(3-hexylthiophene) (P3HT) and their copolymer or derivatives.
